(19) United States
(12) Patent Application Publication
(10) Pub. No.: US 2025/0296195 A1
(43) Pub. Date: Sep. 25, 2025

(54) FLAT-SURFACE POLISHING METHOD AND FLAT-SURFACE POLISHING APPARATUS FOR SEMICONDUCTOR SUBSTRATES

(71) Applicant: NORITAKE CO., LIMITED, Nagoya-shi (JP)

(72) Inventors: Shunta NIWA, Nagoya-shi (JP); Hinako KURAMI, Nagoya-shi (JP)

(73) Assignee: NORITAKE CO., LIMITED, Nagoya-shi (JP)

(21) Appl. No.: 19/077,958

(22) Filed: Mar. 12, 2025

(30) Foreign Application Priority Data
Mar. 22, 2024 (JP) 2024-047274

(51) Int. Cl. B24B 37/005; H01L 21/306

(52) U.S. Cl. CPC B24B 37/0056; H01L 21/30625

(57) ABSTRACT

A flat-surface polishing method of performing a polishing operation for polishing a flat surface of a semiconductor substrate by using a polishing pad with circulation and supply of a polishing fluid including permanganate and water. The flat-surface polishing method includes: (a) during a predetermined time from start of the polishing operation, performing the polishing operation, while maintaining pH of the polishing fluid in a strong acid range by dropping a pH adjuster into the polishing fluid; and (b) after the predetermined time has elapsed and until the polishing operation is completed, performing the polishing operation, while making the pH of the polishing fluid higher than the strong acid range by stopping dropping the pH adjuster into the polishing fluid. Also disclosed is a flat-surface polishing apparatus used for carrying out the flat-surface polishing method.

This application claims priority from Japanese Patent Application No. 2024-047274 filed on Mar. 22, 2024, the disclosure of which is herein incorporated by reference in its entirety.

### FIELD OF THE INVENTION

The present invention relates to a flat-surface polishing method and a flat-surface polishing apparatus for performing a polishing operation for polishing a surface of a semiconductor substrate that is to be used in a semiconductor device, and more particularly relates to techniques for performing rough polishing and finish polishing consecutively in the polishing operation by changing pH of a polishing fluid that is used to be circulated during the polishing operation.

### BACKGROUND OF THE INVENTION

For polishing a semiconductor substrate (semiconductor wafer) such as SiC, there is a flat-surface polishing method disclosed in Japanese Patent No. 6301571, for example. According to the flat-surface polishing method in this Japanese Patent Publication, an acidic polishing fluid including permanganate ion, weak acid and their soluble salt, with its pH adjusted to 0.5-6 or less before start of a polishing operation, is circulated and repeatedly supplied to a polished surface of the semiconductor substrate.

According to the polishing method disclosed in the Japanese Patent Publication, the inclusion of the weak acid and its soluble salt in the polishing fluid serves to suppress a rapid reduction of a polishing rate, which could be caused by a rapid increase of the pH of the polishing fluid due to oxidation of a polished workpiece (i.e., material to be polished) by the permanganate ion in the polishing fluid, so that it is possible to improve a polishing efficiency of the polished surface of the semiconductor substrate as the polished workpiece.

### SUMMARY OF THE INVENTION

However, the above-descried conventional flat-surface polishing method uses action of the weak acid and its soluble salt included in the polishing fluid so as to suppress a rapid increase of the pH of the polishing fluid and increase the pH at a constant rate during the polishing operation, thereby expanding a state in which oxidation of the semiconductor substrate by the permanganate ion can be achieved, as compared to an arrangement in which the polishing fluid does not include the weak acid and its soluble salt, thereby improving the polishing efficiency. As a result, it has been difficult to obtain both an improvement of the polishing efficiency of the semiconductor substrate and an improvement of the quality of the polished surface (low surface roughness) in a single polishing process.

The present invention was made in view of the background art described above. It is therefore an object of the present invention to provide a flat-surface polishing method and a flat-surface polishing apparatus that are capable of improving a polishing efficiency and a quality of a polished surface in a polishing operation for polishing a flat surface of a semiconductor substrate.

Having made various studies under the above-described situation, the present inventors found that, when a flat surface of a semiconductor substrate is to be polished by a polishing operation using a polishing pad with circulation and supply of an acid polishing fluid including potassium permanganate, it is possible to obtain both a high polishing efficiency and an excellent surface smoothness of the polished surface in a single polishing process, by first performing the polishing operation while maintaining pH of the polishing fluid at a predetermined value, i.e., a strong acid value with supply of a pH adjustment liquid into the polishing fluid, and then continuing the polishing operation with the supply of the pH adjustment liquid into the polishing fluid being stopped. The present invention was made based on this finding.

The object indicated above is achieved by the following aspects of the present invention.

According to a first aspect of the invention, there is provided a flat-surface polishing method of performing a polishing operation for polishing a flat surface of a semiconductor substrate by using a polishing pad with circulation and supply of a polishing fluid including permanganate and water. The flat-surface polishing method includes: (a) during a predetermined time from start of the polishing operation, performing the polishing operation, while maintaining pH of the polishing fluid in a strong acid range by dropping a pH adjuster into the polishing fluid; and (b) after the predetermined time has elapsed and until the polishing operation is completed, performing the polishing operation, while making the pH of the polishing fluid higher than the strong acid range by stopping dropping the pH adjuster into the polishing fluid.

According to a second aspect of the invention, there is provided a flat-surface polishing apparatus for performing a polishing operation for polishing a flat surface of a semiconductor substrate by using a polishing pad with circulation and supply of a polishing fluid containing permanganate and water. The flat-surface polishing apparatus includes: (i) a pH-adjuster dropping device configured to drop a pH adjuster into the polishing fluid; and (ii) a polishing control device configured, during a predetermined time from start of the polishing operation, to perform the polishing operation by driving and rotating the polishing pad, while maintaining pH of the polishing fluid in a strong acid range by causing the pH-adjuster dropping device to drop the pH adjuster into the polishing fluid, and configured, after the predetermined time has elapsed and until the polishing operation is completed, to perform the polishing operation by driving and rotating the polishing pad, while making the pH of the polishing fluid higher than the strong acid range by causing the pH-adjuster dropping device to stop dropping the pH adjuster into the polishing fluid. It is noted that the above-described permanganate is an oxoacid salt of manganese, preferably, such as potassium permanganate and sodium permanganate.

According to a third aspect of the invention, in the flat-surface polishing apparatus according to the second aspect of the invention, the predetermined time is a time from the start of polishing operation to 33-50% of an entire time of polishing the flat surface of the semiconductor substrate.

According to a fourth aspect of the invention, in the flat-surface polishing apparatus according to the second or third aspect of the invention, the polishing control device is configured, during the predetermined time from the start of the polishing operation, to perform the polishing operation while maintaining the pH of the polishing fluid in 2.5-3.5 as in the strong acid range

According to a fifth aspect of the invention, in the flat-surface polishing apparatus according to any one of the second through fourth aspects of the invention, the polishing pad includes a base material resin and polishing abrasive grains that are filled in independent pores and/or communication pores provided in the base material resin, and the polishing fluid is a fluid without the polishing abrasive grains.

According to a sixth aspect of the invention, in the flat-surface polishing apparatus according to any one of the second through fifth aspects of the invention, the pH adjuster is a reagent which includes hydrochloric acid, sulfuric acid, nitric acid and/or phosphoric acid, such that the pH of the polishing fluid is maintained in the strong acid range by the pH adjuster.

In the flat-surface polishing method according to the first aspect of the invention, during the predetermined time from the start of the polishing operation, the polishing operation is performed with the pH of the polishing fluid being maintained in the strong acid range by dropping the pH adjuster into the polishing fluid, and after the predetermined time has elapsed and until the polishing operation is completed, the polishing operation is performed with the pH of the polishing fluid being made higher than the strong acid range by stopping dropping the pH adjuster into the polishing fluid. That is, during the predetermined time from the start of the polishing operation, the pH of the polishing fluid is maintained in the strong acid range by dropping the pH adjuster into the polishing fluid, whereby a so-called rough polishing is performed with the polishing being accelerated. Then, after the predetermined time has elapsed, the pH of the polishing fluid is made higher than the strong acid range by stopping dropping the pH adjuster into the polishing fluid, and a so-called finish polishing is performed. Thus, it is possible to obtain both a high polishing efficiency and an excellent surface smoothness of the polished surface in a single polishing process.

In the flat-surface polishing apparatus according to the second aspect of the invention, the pH-adjuster dropping device is configured to drop the pH adjuster into the polishing fluid, and the polishing control device is configured, during the predetermined time from start of the polishing operation, to perform the polishing operation by driving and rotating the polishing pad, while maintaining the pH of the polishing fluid in the strong acid range by causing the pH-adjuster dropping device to drop the pH adjuster into the polishing fluid, and configured, after the predetermined time has elapsed and until the polishing operation is completed, to perform the polishing operation by driving and rotating the polishing pad, while making the pH of the polishing fluid higher than the strong acid range by causing the pH-adjuster dropping device to stop dropping the pH adjuster into the polishing fluid. That is, during the predetermined time from the start of the polishing operation, the pH of the polishing fluid is maintained in the strong acid range by dropping the pH adjuster into the polishing fluid, whereby the so-called rough polishing is performed with the polishing being accelerated. Then, after the predetermined time has elapsed, the pH of the polishing fluid is made higher than the strong acid range by stopping dropping the pH adjuster into the polishing fluid, and the so-called finish polishing is performed. Thus, it is possible to obtain both a high polishing efficiency and an excellent surface smoothness of the polished surface in a single polishing process.

In the flat-surface polishing apparatus according to the third aspect of the invention, the predetermined time is the time from the start of polishing operation to 33-50% of an entire time of polishing the flat surface of the semiconductor substrate, so that it is possible to obtain both the high polishing efficiency and the excellent surface smoothness of the polished surface in a single polishing process. If the predetermined time is shorter than 33% of the entire time of polishing, the high polishing efficiency is unlikely to be obtained. If the predetermined time is longer than 50% of the entire time of polishing, the excellent surface smoothness is unlikely to be obtained.

In the flat-surface polishing apparatus according to the fourth aspect of the invention, the polishing control device is configured, during the predetermined time from the start of the polishing operation, to perform the polishing operation while maintaining the pH of the polishing fluid in 2.5-3.5 as in the strong acid range, so that it is possible to obtain both the high polishing efficiency and the excellent surface smoothness of the polished surface in a single polishing process. If the pH of the polishing fluid is higher than 3.5, the high polishing efficiency is unlikely to be obtained. If the pH of the polishing fluid is lower than 2.5, the surface quality is like to be adversely affected due to an excessive oxidation.

In the flat-surface polishing apparatus according to the fifth aspect of the invention, the polishing pad includes a base material resin and polishing abrasive grains that are filled in independent pores and/or communication pores provided in the base material resin, and the polishing fluid is a fluid without the polishing abrasive grains. The polishing fluid does not contain abrasive grains, so that an environmental impact can be reduced.

In the flat-surface polishing apparatus according to the sixth aspect of the invention, the pH adjuster is a reagent which includes hydrochloric acid, sulfuric acid, nitric acid and/or phosphoric acid, such that the pH of the polishing fluid is maintained in the strong acid range by the pH adjuster. Thus, the pH of the polishing fluid can be maintained in the range of 2.5-3.5.

### BRIEF DESCRIPTION OF THE DRAWINGS

FIG. 1 is a perspective view schematically showing a construction of a double-side polishing apparatus for carrying out a flat-surface polishing method according to an embodiment of the present invention;

FIG. 2 is a view schematically showing, in enlargement, a surface texture of a polishing pad shown in FIG. 1;

FIG. 3 is a graph indicating a relationship between a polishing time and a pH value of a polishing fluid, wherein the relationship was obtained through polishing tests conducted by the present inventors and their collaborators;

FIG. 4 is a table indicating measured values such as a polishing rate, a surface roughness of a Si surface, a surface roughness of a C surface, a surface roughness ratio C/Si and a flatness difference before and after polishing, wherein the measured values were obtained in each of the polishing tests that were different in time in which a pH adjuster was dropped into the polishing fluid;

FIG. 5 is a bar graph showing the polishing rate in each of the polishing tests that were different in time in which the pH adjuster was dropped into the polishing fluid, wherein the polishing tests are shown in the table of FIG.4;

FIG. 6 is a table indicating the surface roughness of the Si surface and the surface roughness of the C surface in each of the polishing tests that were different in time in which the pH adjuster was dropped into the polishing fluid, wherein the polishing tests are shown in the table of FIG.4;

FIG. 7 is a bar graph showing the flatness difference, i.e., TTV (Total Thickness Variation) value, before and after polishing in each of the polishing tests that were different in time in which the pH adjuster was dropped into the polishing fluid, wherein the polishing tests are shown in the table of FIG.4; and

FIG. 8 is a table indicating an evaluation in each of the polishing tests that were different in time in which the pH adjuster was dropped into the polishing fluid, wherein the polishing tests are shown in the table of FIG.4.

### DETAILED DESCRIPTION OF PREFERRED EMBODIMENT

Hereinafter, an embodiment of the invention will be described in detail with reference to the accompanying drawings. It is noted that the drawings are simplified or modified as appropriate, and dimensional ratios and shapes of various parts are not necessarily drawn accurately.

### Embodiment

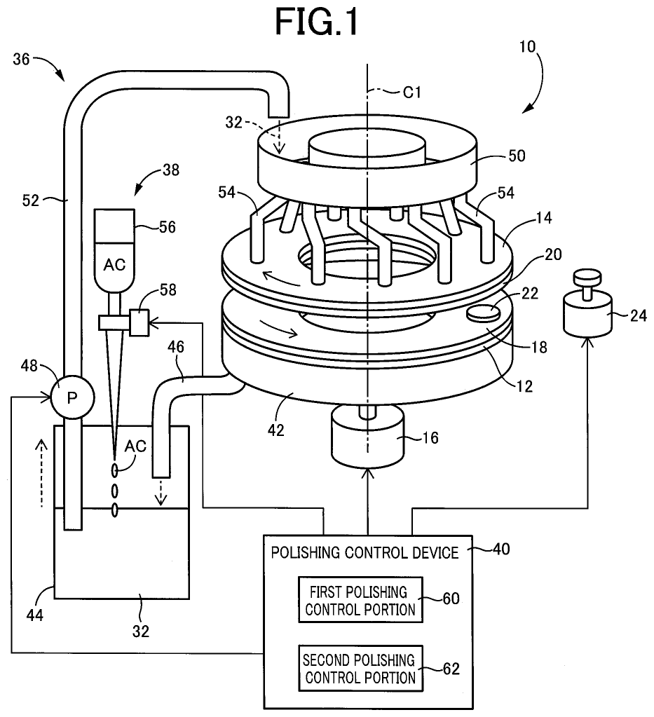

In the present embodiment, a semiconductor substrate 22 such as SiC is polished in accordance with a flat-surface polishing method, by using a flat-surface polishing apparatus in the form of a double-side polishing apparatus 10 shown in FIG. 1. FIG. 1 conceptually shows main parts of the double-side polishing apparatus 10 with a guide-roller fixing table being removed. As shown in FIG. 1, the double-side polishing apparatus 10 includes a pair of polishing platens in the form of a lower polishing platen 12 and an upper polishing platen 14 which are provided to be opposed to each other and which are rotatable relative to each other about a vertical rotation axis C1. The lower polishing platen 12 is driven and rotated at a constant speed in one of opposite directions, for example, as indicated by arrow in FIG. 1, by a platen drive motor 16, while the upper polishing platen 14 is driven and rotated in the other of the opposite directions by the platen drive motor 16 through a connection mechanism that is not shown. A pair of polishing pads in the form of a lower polishing pad 18 and an upper polishing pad 20 are disposed on respective surfaces of the lower and upper polishing platens 12, 14 that are opposed to each other.

Between an upper surface of the lower polishing pad 18 provided on the lower polishing platen 12 and a lower surface of the upper polishing pad 20 provided on the upper polishing platen 14, the circular semiconductor substrate (workpiece) 22 is clamped and held rotatably in a holding hole that is formed through a well-known circular carrier plate (not shown). For example, the carrier plate has outer peripheral teeth, and is arranged to mesh with a central gear and a large-diameter internal gear that are coaxial with the rotation axis C1. The carrier plate performs a planetary motion in which the workpiece is rotated about its axis and revolved about the rotation axis C1, with the central gear or the internal gear being driven and rotated by a carrier drive motor 24.

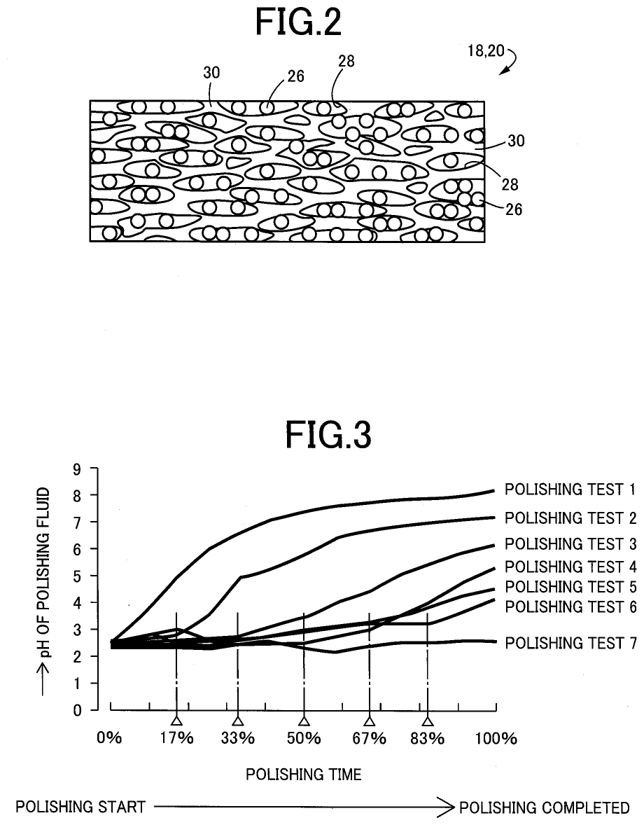

As shown in FIG. 2, each of the lower and upper polishing pads 18, 20 is a polishing pad (LHA pad) constituted by epoxy or PES resin having independent and/or communication pores 28 that store therein polishing abrasive grains 26. Each of the lower and upper polishing pads 18, 20 has an outside diameter of about 700 (mmq) and a thickness of about 2 (mm).

Each of the lower and upper polishing pads 18, 20 is formed in a disc shape with a base material resin 30 made of epoxy or PES resin in which independent and/or communication pores 28 are formed, and a large number of the polishing abrasive grains 26 that are filled in the pores 28 of the base material resin 30, some of which are fixed to the base material resin 30, or some of which are separated from the base material resin 30 during polishing. Therefore, each of the lower and upper polishing pads 18, 20 is called a semi-fixed abrasive-grain polishing pad that contains the polishing abrasive grains 26, and polishing using this abrasive-grain polishing pad is called a semi-fixed abrasive polishing. Each of the lower and upper polishing pads 18, 20 is composed of, for example, about 32 volume % of the polishing abrasive grains 26, about 33 volume % of the base material resin 30, and the pores 28 that occupy the remaining volume. The pores 28 of the base material resin 30, which are formed in a sponge or mesh shape, are formed to be equal to or larger than the polishing abrasive grains 26, and a large number of the polishing abrasive grains 26 are held within the pores 28. The base material resin 30 and each of the polishing abrasive grains 26 are fixed to each other with a necessary and sufficient bonding force. In the present embodiment, each of the lower and upper polishing pads 18, 20 enables polishing of the semiconductor substrate (workpiece) 22 by mechanical polishing action of the polishing abrasive grains 26 supplied by the lower and upper polishing pads 18, 20 themselves, with circulation and supply of a polishing fluid 32 that does not contain the polishing abrasive grains 26, without using a slurry containing the polishing abrasive grains 26 such as colloidal silica, for example, and also chemical polishing action of the polishing fluid 32.

The polishing abrasive grains 26 are preferably silica, but other polishing abrasive grains, such as those containing ceria, alumina, zirconia, silicon carbide, titania, manganese compounds, barium carbonate, chromium oxide and/or iron oxide, may also be used. As the above-described silica, for example, fumed silica (fine silica grains obtained by burning silicon tetrachloride, chlorosilane, etc. at a high temperature in presence of hydrogen and oxygen) is preferably used. An average grain size of the polishing abrasive grains 26 is preferably 0.005 to 3.0 (μm), more preferably 0.005 to 1.0 (μm), more preferably 0.02 to 0.6 (μm), more preferably 0.08 to 0.5 (μm), and even more preferably 0.08 to 0.3 (μm). For example, if the average grain size of the polishing abrasive grains 26 is larger than 3.0 (μm), polishing scratches are likely to occur on the semiconductor substrate (workpiece) 22 due to the polishing abrasive grains 26 that are liberated from the base material resin 30 during a polishing operation described below. Furthermore, if the average grain size of the polishing abrasive grains 26 is smaller than 0.005 (μm), the polishing abrasive grains 26 tend to aggregate, and the polishing scratches are likely to occur on the semiconductor substrate (workpiece) 22 during the polishing operation. The grain size of the polishing abrasive grains 26 is measured by a laser diffraction/scattering method, for example, by a grain size/granularity distribution measuring device, Microtrack MT3300, manufactured by Nikkiso Co., Ltd., and the average grain size is an arithmetic mean of the grain size.

The polishing fluid 32 contains permanganate and water, but does not contain the polishing abrasive grains 26. The permanganate is an oxoacid salt of manganese, preferably, such as potassium permanganate and sodium permanganate. The polishing fluid 32 contains permanganate ions (MnO₂—), for example, at 0.1% by mass to 20% by mass, due to dissolution of the permanganate. The pH of the polishing fluid 32 is adjusted to a range of 2.5 to 3.5 by pH adjuster AC. The pH adjuster AC is a reagent which includes hydrochloric acid, sulfuric acid, nitric acid and/or phosphoric acid, such that the pH of the polishing fluid 32 is maintained in the strong acid range by the pH adjuster AC.

Referring back to FIG. 1, the double-side polishing apparatus 10 includes: a polishing-fluid circulation/supply device 36 configured to circulate and supply the polishing fluid 32 to a polished surface of the semiconductor substrate 22; a pH-adjuster dropping device 38 configured to drop the pH adjuster AC into the polishing fluid 32; and a polishing control device 40 configured to control the polishing operation.

The polishing-fluid circulation/supply device 36 includes: a receiver tank 42 that is disposed on a lower side of the lower polishing pad 18 so as to receive the polishing fluid 32 used to polish the semiconductor substrate 22; a discharge pipe 46 that is configured to guide the polishing fluid 32 received by the receiver tank 42 to a polishing fluid tank 44; a supply pipe 52 that is configured to guide the polishing fluid 32 in the receiver tank 42, which is pumped by a circulation pump 48, into a distribution tank 50; and a plurality of distribution pipes 54 that are connected to respective through-holes formed at equal intervals in a circumferential direction in a bottom wall of the distribution tank 50 and configured to supply the polishing fluid 32 in the distribution tank 50, to a plurality of positions arranged at equal intervals in the circumferential direction on a back surface of the upper polishing pad 20. The polishing fluid 32 discharged from the distribution pipes 54 is supplied to the lower polishing pad 18 and the semiconductor substrates 22 that is disposed on the lower polishing pad 18, through the upper polishing pad 20.

The pH-adjuster dropping device 38 includes: a storage tank 56 configured to store the pH adjuster AC; and a regulator valve 58 configured to regulate an amount of the pH adjuster AC dropped from the storage tank 56 in accordance with a command supplied from the polishing control device 40. The pH-adjuster dropping device 38 is attached above the polishing fluid tank 44.

The polishing control device 40, which is constituted by, for example, a microcomputer, is configured to process input signals in accordance with pre-stored programs, and to control operations of the platen drive motor 16, the carrier drive motor 24, the circulation pump 48 and the regulator valve 58. The polishing control device 40 functionally includes a first polishing control portion 60 and a second polishing control portion 62. The first polishing control portion 60 is configured, during a predetermined time from start of the polishing operation, to perform the polishing operation with a high polishing efficiency, by dropping the pH adjuster AC into the polishing fluid 32, wherein the predetermined time corresponds to 33-50% of an entire time of polishing. The second polishing control portion 62 is configured to perform a finish polishing, by stopping dropping the pH adjuster AC into the polishing fluid 32.

In the double-side polishing apparatus 10 constructed as described above, in response to an operation made on a start switch (not shown), the platen drive motor 16, the carrier drive motor 24, the circulation pump 48 and the regulator valve 58 are operated by the polishing control device 40, whereby the double-side polishing operation of the semiconductor substrate 22 is started. During 33-50% of the entire polishing time from the start of the polishing operation, the regulator valve 58 is controlled by the first polishing control portion 60 whereby the amount of the pH adjuster AC dropped into the polishing fluid 32 is adjusted such that pH of the polishing fluid 32 is maintained in a strong acid range, for example, of 2.5-3.5. At this stage of the polishing operation, the semiconductor substrate 22 is being polished at their both side surfaces at a high polishing rate PR with the pH of the polishing fluid 32 being maintained in the strong acid range of 2.5-3.5.

Next, when 33-50% of the entire time of polishing from the start of the polishing operation has elapsed, the polishing operation is performed with the drop of the pH adjuster AC into the polishing fluid 32 being stopped by the second polishing control portion 62. At this stage of the polishing operation, the finishing operation is performed to reduce a surface roughness Sa, with the pH of the polishing fluid 32 being increased by stop of the drop of the pH adjuster AC into the polishing fluid 32.

### Explanation of Polishing Tests

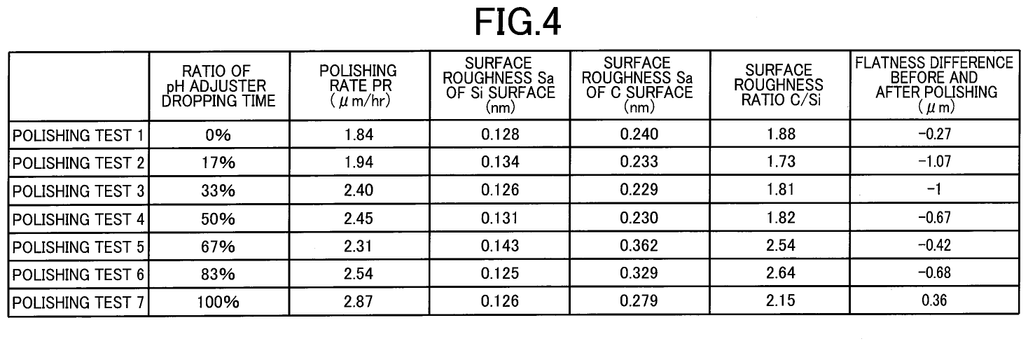

Hereinafter, there will be explained polishing tests conducted by the present inventors and their collaborators under polishing conditions described below. As shown in FIG. 4, the polishing tests 1-7 were conducted with different times in which the pH adjuster AC was dropped into the polishing fluid 32. Specifically, a ratio of the time from the start of polishing operation, to the entire time of polishing was 0%, 17%, 33%, 50% , 67%, 83% and 100% in the polishing tests 1, 2, 3, 4, 5, 6 and 7, respectively. In each of the polishing tests 1-7, a polishing rate PR(μm/hr), a surface roughness Sa of a Si surface, a surface roughness Sa of a C surface and flatness values before and after polishing were measure by using measurement methods described below, and then a surface roughness ratio C/Si and a flatness difference (μm) were calculated.

### Polishing Test Conditions

Double-side polishing apparatus: 9B double side polisher manufactured by SpeedFam
Lower polishing platen rotation speed: 30 rpm (counterclockwise)
Upper polishing platen rotation speed: −10 rpm (clockwise)
Carrier rotation speed: −3 rpm (clockwise)
Carrier revolution speed: −10 rpm (clockwise)
Polishing fluid flow rate: 0.8/min
Polishing fluid volume: 3 L
Polishing operation time: 60 min
Polishing fluid: potassium permanganate solution (0.25 mol/L)
Workpiece: SiC single crystal plate (4 inches φ×0.4 mm t) 3 sheets
Polishing pad: polishing pad involving silica abrasive grains (LHA)
pH adjuster: nitric acid solution of 10 wt %
Drop rate: 0.1 ml/sec

### Method of Measuring pH of Polishing Fluid 32

Using a pH measuring device LAQUA WQ-300 manufactured by Horiba Ltd., a pH measuring electrode of the pH measuring device was attached to the supply pipe 52 of the polishing fluid 32 of the double-side polishing apparatus 10, and the pH of the polishing fluid 32 supplied during the polishing operation was measured.

### Method of Measuring Polishing Rate PR

A mass difference of the SiC single crystal plate before and after the polishing test was measured by using an analytical balance, and an amount of polishing (abrasion thickness) was calculated from a known density of SiC single crystal and a surface area of the polished surface. Then, the polishing rate PR (μm/hr) was calculated by dividing the amount of polishing by a polishing time.

### Method of Measuring Surface Roughness Sa

The surface profiles of the Si surface (0, 0, 1) and C surface (0, 0, −1) of the SiC single crystal plate after the polishing test were measured by using a scanning white light interference microscope (Hitachi High-Tech Corporation VS1330), and the arithmetic mean surface roughness Sa defined in ISO25178 was calculated from the surface profiles.

### Method of Measuring Flatness Difference

Using a flatness measuring device (Tropel FlatMaster 200XRA) manufactured by Corning Corporation, a difference between maximum and minimum thickness values (flatness, TTV value) based on a bottom surface of the SiC single crystal plate was measured for the SiC single crystal plate before and after the polishing test, and the difference between these measurements was calculated as the flatness difference.

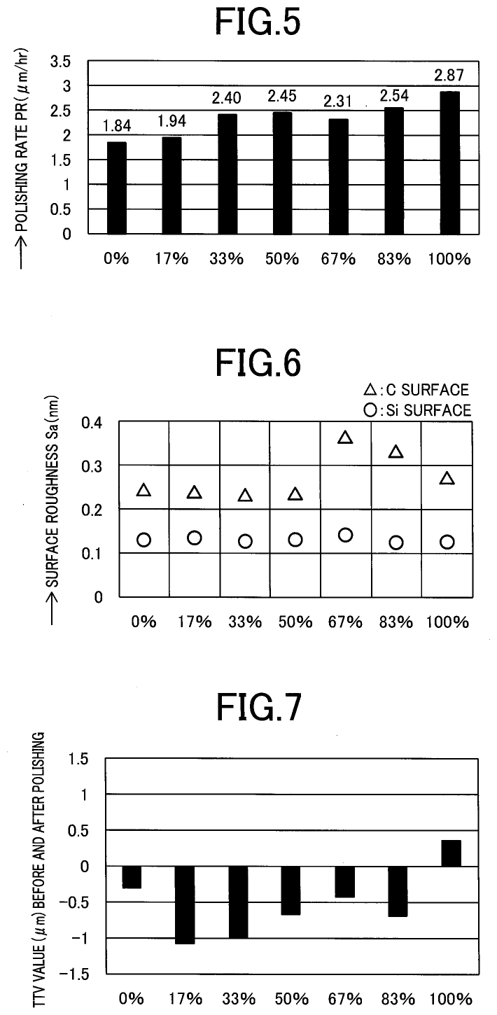

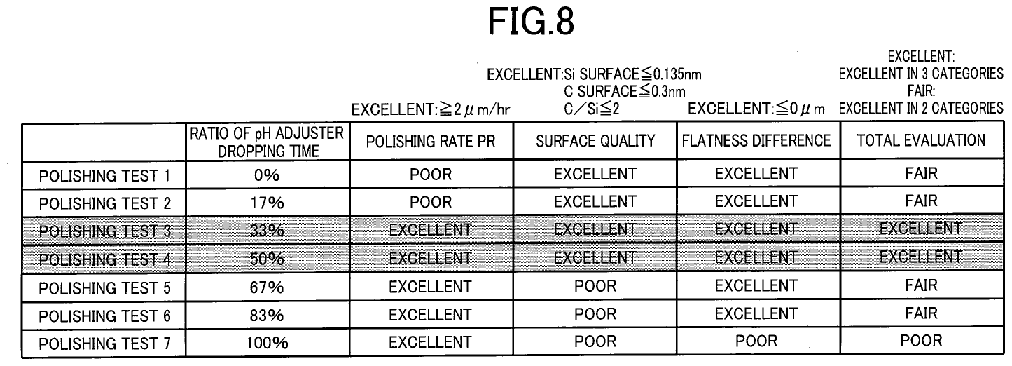

FIG. 3 is a graph indicating a transition of the pH value of the polishing fluid 32 in each of the polishing tests 1-7. FIG. 4 is a table indicating measured values such as the polishing rate PR, the surface roughness Sa of the Si surface, the surface roughness Sa of the C surface, the surface roughness ratio C/Si (i.e., a ratio of the surface roughness Sa of the C surface with respect to the surface roughness Sa of the Si surface) and the flatness difference before and after polishing, wherein the measured values were obtained in each of the polishing tests 1-7. FIG. 5 is a bar graph showing the polishing rate PR in each of the polishing tests 1-7, wherein the polishing rate PR is shown also in FIG. 4. FIG. 6 is a table indicating the surface roughness Sa of the Si surface and the surface roughness Sa of the C surface in each of the polishing tests 1-7, wherein the surface roughness Sa of the Si surface and the surface roughness Sa of the C surface are shown also in FIG. 4. FIG. 7 is a bar graph showing the flatness difference (i.e., TTV value) before and after polishing in each of the polishing tests 1-7, wherein the flatness difference is shown also in FIG. 4. FIG. 8 is a table indicating an evaluation on the measured values shown in FIG. 4, by “EXCELLENT”, “FAIR” and “POOR”.

Regarding the polishing rate PR (μm/hr), a satisfactory result was not obtained in each of the polishing tests 1 and 2 while the satisfactory result was obtained in each of the polishing tests 3-7, wherein an acceptable lower limit was set to 2 μm/hr. Regarding a surface quality (the surface roughness Sa of the Si surface, the surface roughness Sa of the C surface and the surface roughness ratio C/Si), the satisfactory result was not obtained in each of the polishing tests 5-7 while the satisfactory result was obtained in each of the polishing tests 1-4, wherein an acceptable upper limit of the surface roughness Sa of the Si surface was set to 0.135 nm, an acceptable upper limit of the surface roughness Sa of the C surface was set to 0.3 nm, and an acceptable upper limit of the surface roughness ratio C/Si was set to 2. Regarding the flatness difference (μm), the satisfactory result was not obtained in the polishing test 7 while the satisfactory result was obtained in each of the polishing tests 1-6, wherein an acceptable upper limit of the flatness difference was set to 0 μm. Then, in a total evaluation, a high total evaluation (excellent) was given in each of the polishing tests 3 and 4 in which the satisfactory results were obtained in all of the above three categories of evaluations relating to the polishing rate PR, the surface quality and the flatness difference, a medium total evaluation (fair) was given in each of the polishing tests 1, 2, 5 and 6 in which the satisfactory results were obtained in two of the above three categories of evaluations, and a low total evaluation (poor) was given in the polishing test 7 in which the satisfactory result was obtained in only one of the above three categories of evaluations. That is, the high polishing efficiency and the excellent 5 surface roughness Sa were both obtained in the polishing tests 3 and 4 in which the above-described predetermined time from the start of polishing operation is set to 33-50% of the entire time of polishing the SiC substrate as the semiconductor substrate 22.

As described above, in the flat-surface polishing method for the semiconductor substrate 22 according to the present embodiment, during the predetermined time from the start of the polishing operation, the polishing operation is performed with the pH of the polishing fluid 32 being maintained in the strong acid range by dropping the pH adjuster AC into the polishing fluid 32, and after the predetermined time has elapsed and until the polishing operation is completed, the polishing operation is performed with the pH of the polishing fluid 32 being made higher than the strong acid range by stopping dropping the pH adjuster AC into the polishing fluid 32. That is, during the predetermined time from the start of the polishing operation, the pH of the polishing fluid 32 is maintained in the strong acid range by dropping the pH adjuster AC into the polishing fluid 32, whereby a so-called rough polishing is performed with the polishing being accelerated. Then, after the predetermined time has elapsed, the pH of the polishing fluid 32 is made higher than the strong acid range by stopping dropping the pH adjuster AC into the polishing fluid 32, and a so-called finish polishing is performed. Thus, it is possible to obtain both a high polishing efficiency and an excellent surface smoothness of the polished surfaces in a single polishing process.

In the double-side polishing apparatus 10 according to the present embodiment, the pH adjuster dropping device 38 is configured to drop the pH adjuster AC into the polishing fluid 32, and the polishing control device 40 is configured, during the predetermined time from the start of the polishing operation, to perform the polishing operation by driving and rotating the lower and upper polishing pads 18, 20, while maintaining the pH of the polishing fluid 32 in the strong acid range by causing the pH adjuster dropping device 38 to drop the pH adjuster into the polishing fluid 32, and configured, after the predetermined time has elapsed and until the polishing operation is completed, to perform the polishing operation by driving and rotating the lower and upper polishing pads 18, 20, while making the pH of the polishing fluid 32 higher than the strong acid range by causing the pH adjuster dropping device 38 to stop dropping the pH adjuster AC into the polishing fluid 32. That is, during the predetermined time from the start of the polishing operation, the pH of the polishing fluid 32 is maintained in the strong acid range by dropping the pH adjuster AC into the polishing fluid 32, whereby the so-called rough polishing is performed with the polishing being accelerated. Then, after the predetermined time has elapsed, the pH of the polishing fluid 32 is made higher than the strong acid range by stopping dropping the pH adjuster AC into the polishing fluid 32, and the so-called finish polishing is performed. Thus, it is possible to obtain both a high polishing efficiency and an excellent surface smoothness of the polished surfaces in a single polishing process.

In the double-side polishing apparatus 10 according to the present embodiment, the predetermined time is the time from the start of polishing operation to 33-50% of the entire time of polishing the flat surfaces of the semiconductor substrate 22, so that it is possible to obtain both the high polishing efficiency and the excellent surface smoothness of the polished surfaces in a single polishing process. If the predetermined time is shorter than 33% of the entire time of polishing, the high polishing efficiency is unlikely to be obtained. If the predetermined time is longer than 50% of the entire time of polishing, the excellent surface smoothness is unlikely to be obtained.

In the double-side polishing apparatus 10 according to the present embodiment, the polishing control device 40 is configured, during the predetermined time from the start of the polishing operation, to perform the polishing operation while maintaining the pH of the polishing fluid 32 in 2.5-3.5 as in the strong acid range, so that it is possible to obtain both the high polishing efficiency and the excellent surface smoothness of the polished surfaces in a single polishing process. If the pH of the polishing fluid 32 is higher than 3.5, the high polishing efficiency is unlikely to be obtained. If the pH of the polishing fluid 32 is lower than 2.5, the surface quality is like to be adversely affected due to an excessive oxidation.

In the double-side polishing apparatus 10 according to the present embodiment, each of the lower and upper polishing pads 18, 20 includes the base material resin 30 and the polishing abrasive grains 26 that are filled in the independent and/or communication pores 28 provided in the base material resin 30, and the polishing fluid 32 is a fluid without the polishing abrasive grains 26. Since the polishing fluid 32 does not contain the polishing abrasive grains 26, so that an environmental impact can be reduced.

In the double-side polishing apparatus 10 according to the present embodiment, the pH adjuster AC is a reagent which includes hydrochloric acid, sulfuric acid, nitric acid and/or phosphoric acid, such that the pH of the polishing fluid 32 is maintained in the strong acid range by the pH adjuster AC. Thus, the pH of the polishing fluid 32 can be maintained in the range of 2.5-3.5 with the pH adjuster AC being dropped into the polishing fluid 32.

While the preferred embodiment of this invention has been described in detail by reference to the drawings, it is to be understood that the invention may be otherwise embodied.

For example, in the above-described embodiment, SiC as the semiconductor substrate 22 is polished in the double-side polishing apparatus 10. However, the semiconductor substrate 22 to be polished may be Si instead of SiC, and may be any one of other compound semiconductors such as GaN, GaP and AlGaAs.

Further, the base material resin 30 is made of epoxy resin or PES resin. However, the base material resin 30 may also be made of other resins, such as rigid foamed polyurethane resin, polyamide, polyamideimide, polyimide, polyacrylonitrile, polyvinylidene fluoride, cellulose acetate, polyvinyl alcohol, polyester, polyolefin resin, and/or non-foamed polyurethane.

Further, as the silica used in the above-described polishing abrasive grains 26, for example, fumed silica (fine silica grains obtained by burning silicon tetrachloride, chlorosilane, etc. at a high temperature in presence of hydrogen and oxygen) is preferably used.

Further, in the above-described embodiment, the double-side polishing apparatus 10 is used for polishing the both side surfaces of the semiconductor substrate 22 simultaneously with each other. However, a polishing apparatus may be used as the flat-surface polishing apparatus, for one side surface of the semiconductor substrate 22.

Although not specifically illustrated, the present invention can be used with various modifications without departing from the spirit of the invention.

### Nomenclature of Elements

10: double-side polishing apparatus (flat-surface polishing apparatus)
18: lower polishing pad (polishing pad)
20: upper polishing pad (polishing pad)
22: semiconductor substrate
26: polishing abrasive grains
28: independent and/or communication pores
30: base material resin
32: polishing fluid
38: pH-adjuster dropping device
40: polishing control device
AC: pH adjuster

What is claimed is:

1. A flat-surface polishing method of performing a polishing operation for polishing a flat surface of a semiconductor substrate by using a polishing pad with circulation and supply of a polishing fluid including permanganate and water,
the flat-surface polishing method comprising:
during a predetermined time from start of the polishing operation, performing the polishing operation, while maintaining pH of the polishing fluid in a strong acid range by dropping a pH adjuster into the polishing fluid; and
after the predetermined time has elapsed and until the polishing operation is completed, performing the polishing operation, while making the pH of the polishing fluid higher than the strong acid range by stopping dropping the pH adjuster into the polishing fluid.

2. A flat-surface polishing apparatus for performing a polishing operation for polishing a flat surface of a semiconductor substrate by using a polishing pad with circulation and supply of a polishing fluid containing permanganate and water,
the flat-surface polishing apparatus comprising:
a pH-adjuster dropping device configured to drop a pH adjuster into the polishing fluid; and
a polishing control device configured, during a predetermined time from start of the polishing operation, to perform the polishing operation by driving and rotating the polishing pad, while maintaining pH of the polishing fluid in a strong acid range by causing the pH-adjuster dropping device to drop the pH adjuster into the polishing fluid, and configured, after the predetermined time has elapsed and until the polishing operation is completed, to perform the polishing operation by driving and rotating the polishing pad, while making the pH of the polishing fluid higher than the strong acid range by causing the pH-adjuster dropping device to stop dropping the pH adjuster into the polishing fluid.

3. The flat-surface polishing apparatus according to claim 2,
wherein the predetermined time is a time from the start of polishing operation to 33-50% of an entire time of polishing the flat surface of the semiconductor substrate.

4. The flat-surface polishing apparatus according to claim 2,
wherein the polishing control device is configured, during the predetermined time from the start of the polishing operation, to perform the polishing operation while maintaining the pH of the polishing fluid in 2.5-3.5 as in the strong acid range

5. The flat-surface polishing apparatus according to claim 2,
wherein the polishing pad includes a base material resin and polishing abrasive grains that are filled in independent pores and/or communication pores provided in the base material resin, and
wherein the polishing fluid is a fluid without the polishing abrasive grains.

6. The flat-surface polishing apparatus according to claim 2,
wherein the pH adjuster is a reagent which includes hydrochloric acid, sulfuric acid, nitric acid and/or phosphoric acid, such that the pH of the polishing fluid is maintained in the strong acid range by the pH adjuster.
